(19) United States
(12) Patent Application Publication
(10) Pub. No.: US 2021/0032739 A1
(43) Pub. Date: Feb. 4, 2021

(54) DYNAMIC RELEASE MIRROR STRUCTURE FOR LASER-INDUCED FORWARD TRANSFER

(71) Applicant: UNIVERSITY OF OTTAWA, Ottawa (CA)

(72) Inventors: Alan GODFREY, Vanier (CA); Lakshmi DEEPAK KALLEPALLI, Ottawa (CA); Paul CORKUM, Gloucester (CA)

(21) Appl. No.: 16/938,460

(22) Filed: Jul. 24, 2020

Related U.S. Application Data
(60) Provisional application No. 62/879,869, filed on Jul. 29, 2019.

(51) Int. Cl. C23C 14/04; C23C 14/28

(52) U.S. Cl. CPC C23C 14/048; C23C 14/28

(57) ABSTRACT

A method and apparatus for laser-induced forward transfer (LIFT) processing including a dynamic release mirror structure (DRMS) for desorbing delicate materials from a first surface and depositing a resultant formation of a portion of the materials on a second surface without damaging the material or coating the material with contaminants. The DRMS includes a lower-situated absorbing polymer layer on a transparent substrate. The lower-situated absorbing polymer layer is coated with a metal layer to reflect light of a laser pulse. The metal layer is topped by an upper-situated polymer cap layer. The 3-part layering of the metal layer sandwiched between the upper and lower polymer layers is variable in terms of materials and thickness to tune DRMS operational characteristics.

### RELATED APPLICATIONS

This application is a non-provisional patent application which claims the benefit of U.S. provisional application No. 62/879,869 filed on Jul. 29, 2019.

### TECHNICAL FIELD

The present invention relates to a method and apparatus for laser-induced forward transfer (LIFT) processing. More specifically, the present invention relates to providing a dynamic release mirror structure for LIFT processing of delicate materials from a surface without damage or contamination thereof.

### BACKGROUND

LIFT processing is a digital printing technique that uses a pulsed laser beam as the driving force to project material from a donor thin film toward a receiving substrate upon which that material is deposited. This working principle allows LIFT to operate with both solid and liquid donor films, which provides the technique with a broad spectrum of printable materials, thus being very competitive over other digital technologies, like inkjet printing. LIFT accesses a wide range of ink viscosities and loading particle sizes, and the possibility of printing from solid films allows the single-step printing of multilayers and entire devices, and even makes possible 3D printing. This versatility translates, in turn, into a broad field of applications, from graphics production to printed electronics, and from the fabrication of chemical sensors to tissue engineering.

More particularly, LIFT mainly employs a high-powered pulse laser and two coplanar glass slides. In relation to, for example biological applications, an upper slide, called “donor-slide”, is coated with an energy absorption metal layer (also known as a dynamic release layer or sacrificial layer) and a layer of material containing cells. Laser pulses are focused on the metal layer via the upper slide, evaporating the laser absorbing layer locally. During the process, the laser pulse generates a high gas pressure that transfers the underlying cell compound toward the lower slide, referred to as the “collector-slide” or “receiver.” Metallic layers, upon interaction with the laser, tend to fragment leading to contaminated LIFT. Hence, advanced versions of LIFT have adopted polymers as DRL materials. The biological materials containing cells are usually a culture medium or hydrogel that provides a humid environment, thus preventing cell dehydration. Hydrogel has the additional function of sustaining cell structure.

Other techniques using LIFT include microprinting of diffractive optical structures and computer-generated holograms, writing active and passive mesoscopic circuit elements, and arranging pad arrays in microelectronic packaging, etc., all accomplished by basically using pulsed lasers to remove a thin film material from a transparent support substrate and deposit a select portion of the thin film material onto a suitable receiving substrate.

As may be seen from FIG. 1, a typical LIFT structure will simultaneously provide for the desorption and deposition of materials Typically, a laser pulse 10, using nanosecond (ns), picosecond (ps), or femtosecond (fs) duration, is focused through a glass layer 11 onto a dynamic release layer (DRL) 12 formed of a polymer material. The DRL 12 undergoes physical and/or chemical change leading to vaporization and/or deformation (e.g., blister formation) of the DRL 12. This process provides a physical thrust for transfer (depicted at 16 by dotted lines) to a layer of transfer material 17, which is deposited onto a receiver substrate 14. As seen in FIG. 1, the layer of transfer material 17 is a formed as a donor side whereby the material 17 moves to become receiver side material 15. The transfer material 17 and receiver substrate 14 are separated by spacers 13a, 13b of typically 1-10 μm thickness. In such typical LIFT structure, the laser directly interacts with the material which leads to contamination.

It is known that the wavelength of the given laser, the laser's pulse duration, and choice of material forming the DRL play an important role in the effective transfer of sensitive materials. In most implementations of LIFT, ns lasers are used because the wavelengths associated (approximately 300-400 nm in UV) with these lasers are close to the absorption band of typical DRL materials. With ns-LIFT, typically 100 μm² areas are deposited onto the receiver. However, when the target size of desorption is below the diffraction limit (approximately 200 nm in diameter), ns-LIFT is not a solution as precise deposition of laser energy over a small region is required. This cannot be achieved with linear absorption of nanosecond pulses.

Nonlinear interaction of ultrafast lasers with materials has allowed effective spot sizes (i.e., beam radius') below the diffraction limit, though the nonlinear interaction leads to DRL modification only at the peak intensities of a femtosecond pulse, thus confining the modification size. However, typical disadvantages with fs-LIFT are that transmission of intensities below the nonlinear absorption threshold often interact in problematic ways with sensitive transfer materials, and there tends to be a small working pulse energy range for contaminant-free or damage-free fs-LIFT, compared to ns-LIFT.

Accordingly, there is a need to overcome the deficiencies of the known methods and structures related to LIFT processing.

### SUMMARY

The present invention provides a method and apparatus for laser-induced forward transfer (LIFT) processing including a dynamic release mirror structure (DRMS) for desorbing delicate materials from a first surface and depositing a resultant formation of a portion of the materials on a second surface without damaging the material or coating the material with contaminants. The DRMS includes a lower-situated absorbing polymer layer on a transparent substrate. The lower-situated absorbing polymer layer is coated with a metal layer to reflect light of a laser pulse. The metal layer is topped by an upper-situated polymer cap layer. The 3-part layering of the metal layer sandwiched between the upper and lower polymer layers is variable in terms of materials and thickness to tune DRMS operational characteristics.

In a first aspect, the present invention provides a method of transferring a material between surfaces, the method including: depositing a layer of donor material on a release structure having a first polymer layer, a second polymer layer, and a reflective layer located therebetween; providing sufficient thrust to eject a portion of the layer of donor material onto a receiver substrate.

In a second aspect, the present invention provides a release structure for laser-induced forward transfer processing, the structure including: a lower-situated absorbing polymer layer on a transparent substrate; an upper-situated polymer cap layer upon which a donor material resides; a metal layer sandwiched between the absorbing polymer layer and the polymer cap layer; and wherein the metal layer constrains a laser pulse directed from the transparent substrate to the donor material.

### BRIEF DESCRIPTION OF THE DRAWINGS

The present invention will now be described by reference to the following figures, in which identical reference numerals refer to identical elements and in which:

FIG. 1 is a typical laser-induced forward transfer (LIFT) structure;

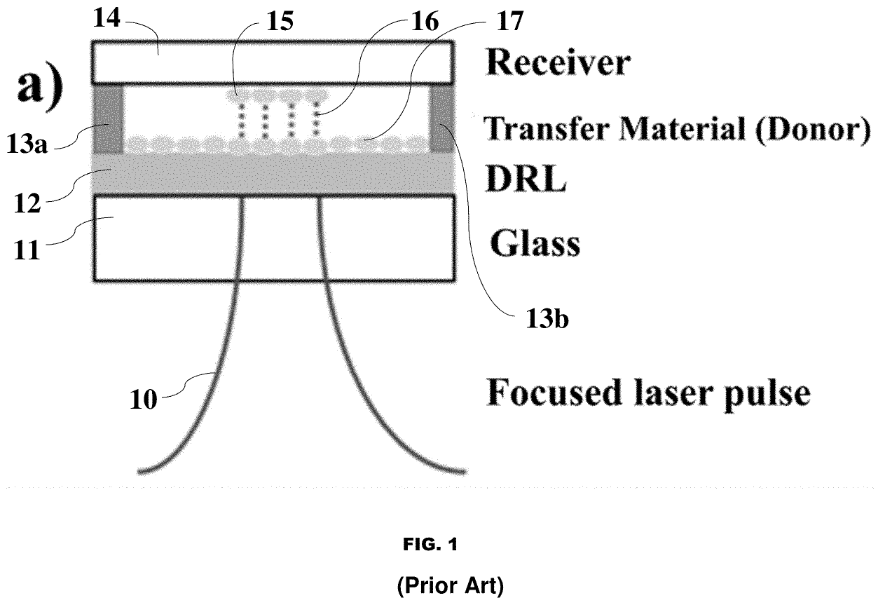

FIG. 2 is a LIFT structure including a mirrored layer formed by a dynamic release mirror structure (DRMS) in accordance with the present invention;

FIG. 3 shows laser-induced formations produced by the LIFT structure with DRMS in accordance with the present invention;

FIG. 4 shows laser-induced formations produced by a typical LIFT structure.

### DETAILED DESCRIPTION

The present invention provides a method and apparatus for laser-induced forward transfer (LIFT) processing that includes a dynamic release mirror structure (DRMS) for desorbing delicate materials from a first surface and depositing a resultant formation of a portion of the materials on a second surface without damaging the material or coating the material with contaminants.

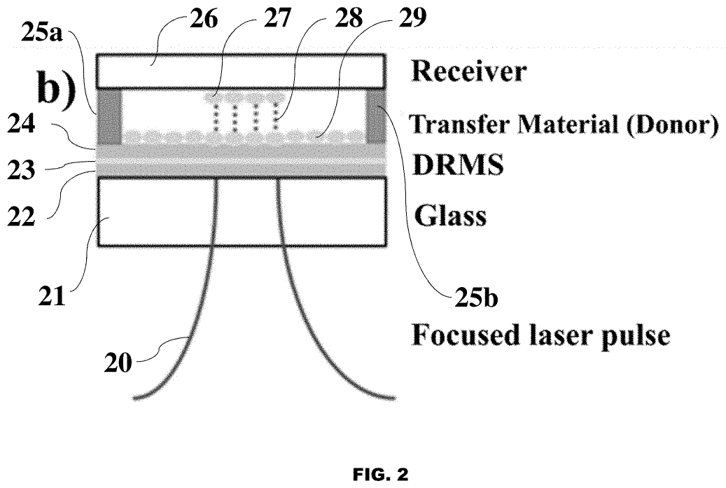

With reference to FIG. 2, the present invention is shown to provide LIFT with DRMS. Here, a laser pulse 20, using nanosecond (ns), picosecond (ps), or femtosecond (fs) lasers, is focused through a transparent substrate (e.g., glass layer) 21 onto a DRMS in accordance with the invention. The DRMS consists of an absorbing polymer layer 22 on the transparent substrate 21, coated with a metal layer 23 to reflect light of the laser pulse 20, and followed again by a polymer cap layer 24 atop the metal layer 23. This 3-part layering of the metal layer 23 sandwiched between the lower-situated absorbing polymer layer 22 and the upper-situated polymer cap layer 24 is structurally and functionally different from a typical DRL as discussed further hereinbelow.

Upon excitation by the laser, the cap layer 24 undergoes physical and/or chemical changes leading to vaporization and/or deformation (e.g., blister formation) of the cap layer 24. This process provides a physical thrust for transfer (depicted at 28 by dotted lines) acting upon a layer of transfer material 29, which is deposited onto a receiver substrate 26. As seen in FIG. 2, the layer of transfer material 29 is formed as a donor side whereby the material 29 moves from the polymer cap layer 24 towards the receiver substrate 26 so as to become receiver side material 27. The polymer cap layer 24 and receiver substrate 26 are separated by spacers 25a, 25b of typically 1-10 μm thickness within which the activity of the LIFT process occurs.

While the basic outcome is similar to typical LIFT processing, the present invention provides improved handling of transferred material. When irradiated with the laser pulse 20 which partially passes through the polymer layer 22, the material 29 to be desorbed is protected from intense light by the metal layer 23. When irradiated through the substrate 21 with the short laser pulse 20, the deposited energy is efficiently used as light passes through the underlying polymer medium twice: first through the lower situated absorbing polymer layer 22 and second through the upper situated polymer cap layer 24. Thus, direct interaction of the laser emission with the transferred material is substantially reduced. Such efficient use of the deposited energy refers to the fact that a laser pulse is reflected back into the underlying polymer layer, giving the pulse a second pass to deposit more energy into the polymer. Furthermore, the back-reflection causes an interference effect between the reflected leading portion of the pulse and the pulse's incoming tail end (a “standing wave interference effect”). This interference leads to enhancement of the intensity inside the polymer. This provides a substantial boost to absorption efficiency for any nonlinear absorption process, where the absorption scales as powers (e.g., square, cube, etc.) of the local intensity in the material. In trials of the present invention, a reduction was exhibited in the amount of energy required to form a blister by a factor of 6. This effect advantageously increases the efficiency available for contaminant-free LIFT in contrast to a single dynamic release layer.

In accordance with the present invention, the lower-situated absorbing polymer layer 22 and the upper-situated polymer cap layer 24 (i.e., the base and capping polymer layers) may vary in terms of both the particular material chosen and in terms of their thicknesses. Of particular advantage over typical LIFT processing, the chosen material and relative thicknesses of the polymer layers within the DRMS may be independently chosen in order to tune the capping layer expansion rate, and hence ejection speed of the donor material.

It should be noted that selection of the bottom layer to be a more strongly absorbing substance makes the present invention more efficient at using laser pulse energy. Also, choosing material of the polymer layers so as to have a particular absorption mechanism (i.e., linear or nonlinear absorption) may be advantageous depending on the target desorption size. For example, strong linear absorption would help obtain the largest features possible, whereas high-order nonlinear absorption may be used to obtain sub-micron features. The top polymer layer may be chosen to be a highly elastic material (e.g., elastomer-doped polymer), which may help to avoid blister rupture.

In terms of varying the layer thicknesses in the present DRMSs, one should consider the ratios of laser penetration depth to total film thickness acting upon single polymer layers. The larger the relative extent of laser penetration, the taller the blisters may rose. For example, for a given set of laser parameters, a 1.3-micron polyimide film may provide a blister height of 1.3 microns, whereas a 3.5-micron polyimide film may only provide a height of 200 nm. In general, the thinner a top layer of polymer may be formed, the less resistance the film will have to the expansion process, so less pulse energy is required. This allows one to select the relative extent of laser penetration simply by prescribing layer thicknesses, giving the additional benefit that laser energy is not wasted on overcoming the inertia/internal resistance of an unnecessarily thick polymer film.

As previously mentioned, the LIFT process is powered by light that is absorbed in a polymer, which heats and vaporizes the polymer. The resulting polymer expansion locally releases any material coated on the polymer surface. The present invention using DRMS greatly extends the range of lasers that may be used by allowing non-resonant multiphoton absorption to power the LIFT process. This is accomplished by the inventive 3-layer DRMS structure where the middle layer is a reflecting material. This enables transfer of delicate materials from one surface to another without damaging or contaminating the transfer material, nor exposing the material to damaging laser radiation. The present invention may therefore vastly improve transfer of intact electronic circuits, 3-D printing or releasing biological materials from a surface.

The DRMS in accordance with the present invention thus consists of polymer and metal layers. The central metal layer limits laser penetration into the DRMS and prevents transmission of intensities below the nonlinear absorption threshold in the case of a nonlinearly-absorbing polymer layer. Advantageously, the DRMS in combination with the overall LIFT structure may be utilized substantially independent of the pulse duration and wavelength of the applied laser. The mirror layer effectively restricts the penetration of the laser emissions into the DRMS. The present invention thus enables transmission of intensities below the nonlinear absorption threshold even with regard to sensitive transfer material. As well, the present invention enables a greater working pulse energy range for contaminant-free or damage-free fs-LIFT, compared to ns-LIFT. It should be understood that the reflective layer is intended to do maximize exposure of the lower polymer layer while preventing exposure of the top layer. This is of course not a concern, since the bottom layer is intended to be destroyed all along. The bottom layer gives rise to the expansion process, when the bottom layer is converted into extremely hot material by the intense laser pulse.

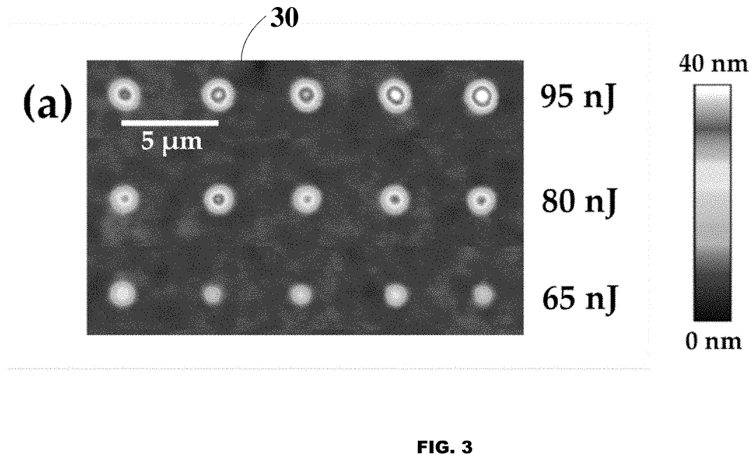

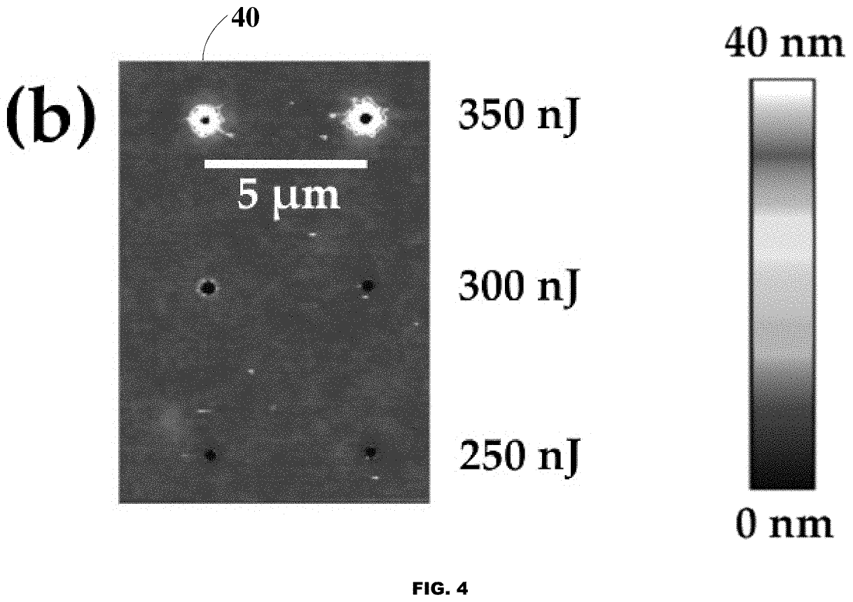

With reference to FIG. 3, a series of laser-induced formations are shown which were produced by the LIFT structure with DRMS in accordance with the present invention. Here, a DRMS consisting of a 400 nm poly(methyl-methacrylate) (PMMA) layer coated on a glass coverslip, a 110 nm gold layer on top of the PMMA layer, and a capping layer of 400 nm PMMA 30 which is seen in the left image of FIG. 3. Each row was created using the pulses energies as shown. The formations as shown were the results of a DRMS with PMMA being acted upon by an 800 nm laser. As clearly seen from FIG. 3, the formation of blisters occurred even at low energies—i.e., 95 nJ, 80 nJ, and 65 nJ. In contrast, FIG. 4 reveals that, without the added mirror layer, intact blisters could not be formed in 800 nm of homogeneous PMMA.

More specifically, with reference to FIG. 4, there is shown laser-induced formations produced by a typical LIFT structure (i.e., without DRMS and with a homogeneous 800 nm PMMA). Here, ruptured blisters formed in the PMMA-only film 40 near the damage threshold. Without the added mirror layer, intact blisters could not be created. Thus, one skilled in the art would understand that the energy dynamic range was greatly increased with the DRMS approach of the present invention.

While known LIFT structures typically utilize either a single layer of material for the dynamic release layer or even no dynamic release layer, the present invention provides a multi-layer release structure in the form of the above-described DRMS which allows much more flexibility in both the choice of lasers and absorbing polymers. As the penetration of the laser may be moderated by placement of the mirror layer in accordance with the inventive DRMS, more control may be added to the LIFT process. Moreover, the present inventive DRMS lowers the intensity required for nonlinear interaction within the LIFT process.

Still further, the present inventive DRMS with LIFT supports a broad range of excitation wavelengths whereby nonlinear absorption may be driven in a large variety of materials without the laser reaching the transfer material. In contrast, known LIFT techniques tend to require very careful choice of laser wavelength and material properties. As the present invention supports linear or nonlinear absorption, DRMS in accordance with the invention may advantageously be utilized for micro-LIFT (sizes more than 5 μm) and nano-LIFT (sizes below the diffraction limit). It should be understood that nonlinear absorption processes transmit intensity below the absorption threshold, which is substantially eliminated by a reflecting layer.

It should be understood that any excitation wavelength may be utilized, provided that the laser may be transmitted through the substrate and is strongly reflected by the mirror layer. This allows nearly any absorption process to be driven, since the interference effect allows for a local intensity spike created in the polymer. This is true as long as the polymer has a thickness of at least on the order of a quarter-wavelength of the driving laser in the polymer medium. Otherwise, the absorption process would have less of an efficiency boost, but would still be possible to drive absorption, and the mirror layer would still protect material on the other side.

The present inventive DRMS with LIFT may be implemented in a variety of applications including, without limitation, lifting cells from a surface “on-demand”, cell deposition, precision placement of material for additive 3-D printing, or transferring electronic components for printable electronics. The present invention provides several advantages over typical LIFT structures including: improving the practicality of fs-LIFT by greatly expanding working energy ranges in fs-LIFT, substantially eliminating any chance of contamination from interaction of light with the transfer material, allowing for a large variety of absorbing materials in DRMS to be used with a given laser, and allowing the base and capping polymer layers to be independently chosen.

A person understanding this invention may now conceive of alternative structures and embodiments or variations of the above all of which are intended to fall within the scope of the invention as defined in the claims that follow.

We claim:

1) A method of transferring a material between surfaces, said method comprising:
depositing a layer of donor material on a release structure having a first polymer layer, a second polymer layer, and a reflective layer located therebetween;
providing a pulsed laser emission through said release structure sufficient to eject a portion of said layer of donor material onto a receiver substrate.

2) The method as claimed in claim 1, further including:
selecting said first polymer layer and said second polymer layer to vary an expansion rate below said portion of said layer of donor material that is ejected onto said receiver substrate.

3) The method as claimed in claim 1, further including:
selecting said second polymer layer to vary an expansion rate below said portion of said layer of donor material that is ejected onto said receiver substrate.

4) The method as claimed in claim 1, further including:
selecting said reflective layer to vary an expansion rate below said portion of said layer of donor material that is ejected onto said receiver substrate.

5) The method as claimed in any of claim 1, wherein one or more of each of said first polymer layer, said second polymer layer, and said reflective layer are selected based upon either material or thickness.

6) The method as claimed in any of claim 1, wherein one or more of each of said first polymer layer, said second polymer layer, and said reflective layer are selected so as to vary said expansion rate.

7) A release structure for laser-induced forward transfer processing, said structure comprising:
a lower-situated absorbing polymer layer on a transparent substrate;
an upper-situated polymer cap layer upon which a donor material resides;
a metal layer sandwiched between said absorbing polymer layer and said polymer cap layer;
wherein said metal layer constrains a laser pulse directed from said transparent substrate to said donor material.

8) The release structure as claimed in claim 7, wherein said lower-situated absorbing polymer layer, said upper-situated polymer cap layer, and said metal layer are each independently chosen with regard to material and relative thickness.

9) The release structure as claimed in claim 7, wherein said polymer cap layer has an expansion rate that correlates to an ejection speed of said donor material residing upon said polymer cap layer, said expansion rate being determined by physical attributes of said lower-situated absorbing polymer layer, said upper-situated polymer cap layer, and said metal layer.

10) The release structure as claimed in claim 9, wherein said physical attributes include a material forming said lower-situated absorbing polymer layer, said upper-situated polymer cap layer, and said metal layer.

11) The release structure as claimed in claim 9, wherein said physical attributes include a thickness of said lower-situated absorbing polymer layer, said upper-situated polymer cap layer, and said metal layer.

12) The release structure as claimed in claim 7, wherein said metal layer is gold.

13) The release structure as claimed in claim 7, wherein said absorbing polymer layer and said polymer cap layer are each formed from poly(methyl-methacrylate).
